(19) United States
(12) Patent Application Publication
(10) Pub. No.: US 2026/0262365 A1
(43) Pub. Date: Sep. 3, 2026

(54) INTELLIGENT VISION SYSTEM BASED ON PHOTON-MODULATED ELECTROCHEMICAL DOPING

(71) Applicant: Purdue Research Foundation, West Lafayette, IN (US)

(72) Inventors: Ke CHEN, Mountain view, CA (US); Jianguo MEI, West Lafayette, IN (US)

(73) Assignee: Purdue Research Foundation, West Lafayette, IN (US)

(21) Appl. No.: 19/155,546

(22) PCT Filed: Mar. 7, 2024
(86) PCT No.: PCT/US2024/018960

§ 371 Date: Aug. 11, 2025

Related U.S. Application Data
(60) Provisional application No. 63/451,003, filed on Mar. 9, 2023.

(51) Int. Cl. H10K 30/65

(52) U.S. Cl. CPC H10K 30/65

(57) ABSTRACT

An intelligent vision system, including a training array of photonic-organic electrochemical transistor (POECT) devices, each including a substrate, three terminals including a gate, a drain, and a source disposed over the substrate, wherein space between the drain and the source forms a channel, an electrolyte in fluid and electrical communication with the gate and the channel, wherein the channel is formed of a photoactive layer composed of donor-acceptor bulk heterojunction interfaces, each POECT device of the training array provides a memory feature when exposed to light, wherein an image to be recognized is imprinted on the training array by exposing the training array with light corresponding with the image to be recognized, and a discriminator configured to compare the training array with a test model associated with an image to be tested against the image to be recognized, wherein the discriminator signals a match or a mismatch based on a comparison.

### CROSS-REFERENCE TO RELATED APPLICATIONS

This patent application claims priority to a U.S. provisional patent application Ser. 63/451,003 filed Mar. 9, 2023, contents of which are hereby incorporated by reference in its entirety into the present disclosure.

### STATEMENT REGARDING GOVERNMENT FUNDING

None.

### TECHNICAL FIELD

The present disclosure generally relates to biosensors, and in particular to a sensor that can be used in an intelligent vision system including an image capture subsystem, an image memory subsystem, and an image recognition subsystem.

### BACKGROUND

This section introduces aspects that may help facilitate a better understanding of the disclosure. Accordingly, these statements are to be read in this light and are not to be understood as admissions about what is or is not prior art.

Bioinspired electronics are devices or systems that can emulate the functions of living things. To develop future advanced bioelectronics or humanoid robots, there has been a surge of interest in constructing synaptic or neuromorphic devices that can think and memorize like human brains. With the advancement of brain-machine interfaces and prosthetics, research emerges to interface these intelligent devices with living systems. Organic synaptic devices are particularly suitable for this purpose due to their mechanical comfortability, biocompatibility and responsivity to analytes in biological media. In the past two decades, major efforts have been made to investigate organic electronic synapses with both input and output as electrical signals.

To date, three-terminal field-effect transistors (FETs) are one of major platforms for organic biosensors. In the devices, the photon-induced charge separation, transport, and trapping at channel/dielectric interfaces are regarded as the primary working mechanism for biosensors, e.g., photonic synaptic sensors, behaviors. Based on this mechanism, the biosensors can emulate biological functions such as short-term plasticity (STP), long-term plasticity (LTP), and spiking time-dependent plasticity (STDP). However, there are some intrinsic challenges in implementation of this type of devices. For example, achieving linear multilevel conductance states is still difficult with FETs, due to the charge screening effects at the interfaces. The photocurrents of FET devices are often limited even at high programming voltages, which results in ambiguous short term/long term memory signals and limits their utilities in high density computing. Therefore, it is crucial to have a device platform that can generate considerable photocurrent at low programming voltages, provide multilevel conductance states, and enable light-gated ionic/electronic coupling for constructing future electronics-biological interfaces.

Therefore, there is an unmet need for a novel sensor arrangement that can be used in an intelligent vision system which can provide a memory function.

### SUMMARY

To be completed at the end of the drafting process.

### BRIEF DESCRIPTION OF DRAWINGS

FIG. 1a provides top view and sideview schematics of a photonic synaptic device according to the present disclosure.

FIG. 1b is a schematic of the photonic synaptic device of the present disclosure with various components called out as well as a series of voltage and current graphs depicting the operation of the photonic synaptic device of the present disclosure.

FIG. 2 is a schematic illustration of a biological synapse and a schematic illustration of the photonic synaptic device of the present disclosure.

FIG. 3a is a graph of postsynaptic current (PSC) in μA vs. time in seconds, the tenth pulse (A₁₀) is higher than the second (A₂) and the first light pulse (A₁).

FIG. 3b is a graph of Paired pulse facilitation (PPF) index vs. time interval in s.

FIG. 3c is a graph of PSC in μA vs. time in seconds with varying pulse numbers.

FIGS. 3d and 3e FIGS. 3d-3e are graphs of I_{DS} in μA and −ΔI_{DS} both vs. time in seconds, showing prolonging pulse width (7.0 mW/cm²) in FIG. 3d, and decreasing pulse intervals (7.0 mW/cm², tₚ=0.4 s) in FIG. 3e.

FIG. 3f is a simplistic schematic of known processes of human acquiring knowledge through three processes: learning, forgetting, and relearning.

FIG. 3g is a graph of the processes shown in FIG. 3f but with the approach of the present disclosure.

FIG. 3h is a graph of −ΔI_{DS} in μA vs. time in seconds, after responding to a 60-second light pulse.

FIG. 4a is a schematic illustration showing photon-modulated electrochemical doping, in which light-induced charge carriers in the bulk heterojunctions leads to ion transport from the electrolyte for charge compensation are shown.

FIG. 4b is a schematic and graph used to validate the photon-modulated electrochemical doping, in which an in-situ spectroscopic experiment is performed before and after light exposure.

FIG. 4c is a schematic illustration of a five-electrode electrochemical cell, where two extra electrodes (E1, E2, e.g., Pt electrodes) are added to the photonic synaptic device of the present disclosure to monitor the ion migration.

FIG. 4d are graphs that provide simultaneous channel current change (I_{DS}) in μA and open circuit potential (OCP_{E1/E2}) in V both vs. time in seconds showing change in response to light illumination.

FIG. 4e is a graph showing [6,6]-phenyl C61-butyric acid methylester (PCBM) anion radical/polaron transient absorption decay kinetic trace of pristine P₃HT/PCBM film and the film with electrolyte (as called out in the figure)—the plots are normalized to facilitate comparison.

FIG. 4f provides a graph of −I_{DS} in μA vs. V_{G} in Volts showing the transfer characteristics of the device.

FIG. 4g is a graph of −ΔI_{DS} in μA vs. time in seconds providing an illustration of photonic response at V_{G}=−0.6 V and V_{DS}=−0.8 V of the device in different electrolytes.

FIG. 4h is a graph of −I_{DS} in μA vs. time in seconds providing an illustration of photonic response of the device to hand waves in an ambient light environment with LiPF₆ based gel electrolyte.

FIG. 4i is a graph showing results from a spectroelectrochemistry experiment.

FIG. 5a is an illustration of the image perception and memorization of letter “L” on which L-shaped light was projected onto a 4×5 synaptic array composed of the photonic synaptic devices of the present disclosure, where the devices at letter position were stimulated with light intensity of 7.0 mW/cm², and the background devices were with light intensity of 2.0 mW/cm².

FIG. 5b provides resulting current mapping of the array right after the light is deactivated and 200 s thereafter. Specifically, after 200 seconds of the light off, this distribution of current difference can still be observed, demonstrating the device's pattern memory capabilities.

FIG. 5c provides results of a device array fabrication with 18,000 transistors on a 2.5×5 cm² glass substrate.

FIG. 5d is a graph of I_{DS} in μA vs V_{DS} in volts.

FIG. 5e is a graph of −ΔI_{DS} in μA vs. time in seconds.

FIG. 5f is a graph of −I_{DS} in μA vs. V_{G} in volts, in which the transfer curves distribution of the devices is relatively concentrated.

FIG. 5g is a histogram of −ΔI_{DS} in μA pf 81 devices, the distribution of photonic response of these 81 devices is narrow, with 94% of devices exhibiting current change of more than 0.8 μA.

FIG. 5h is a series of graphs of −ΔI_{DS} in μA vs. time in seconds providing photonic response of synaptic devices in a 4×5 synaptic array.

FIG. 5i is a schematic of a device fabrication process of the device of the present disclosure.

FIG. 6a is a schematic of a synaptic array that was trained with nine grayscale face images of a woman with distinct facial expression and orientations.

FIG. 6b is a subset of the array of FIG. 6a for building the face recognition model, which has high memory current and thus can represent the face characteristic outline.

FIG. 6c provides graphs of current vs. time for idle and activated devices.

FIG. 6d provides an array which shows low activation rate to true negative images, while it also shows high activation rate to true positive images, even when these images are from different orientation or added with signal noise compared to the training face images.

FIG. 6e is a graph of −ΔI_{DS} in μA vs. light intensity in mW/cm² indicating a light induced nonvolatile current change as a function of light intensity.

FIG. 6f is a graph of a function surface showing the memory current-dependent and light intensity-dependent transient current change.

FIG. 6g is a schematic of real-time wights which can be read out through drain current without influencing the device conductance in the three-terminal device structure of the present disclosure.

FIG. 6h is a graph which shows predicted photocurrents for all feature devices in a positive case using the training face images, trained memories and the function surface.

FIG. 6i is a schematic which provides simulation results of hardware neural networks using optical synapses including configuration of a single-layer perceptron, configuration of a LeNet CNN model, recognition rates of two models with respect to training epochs, and evaluation of model training progression using synaptic weights visualization and Grad-CAM heatmap.

FIG. 6j is a graph which provide parameter fitting of the device potentiation and depression pulse trains with 60 representative weight states.

### DETAILED DESCRIPTION

For the purposes of promoting an understanding of the principles in the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 10%, within 5%, or within 1% of a stated value or of a stated limit of a range.

In the present disclosure, the term “substantially” can allow for a degree of variability in a value or range, for example, within 90%, within 95%, or within 99% of a stated value or of a stated limit of a range.

A novel sensor arrangement is disclosed that can be used in an intelligent vision system and which can provide a memory function. Towards this end, a photonic-organic electrochemical transistor (POECT)-based technology is utilized in a novel arrangement suitable for use in an intelligent vision system including an image capture subsystem, an image memory subsystem, and an image recognition subsystem. As a demonstration, a single-layer synapse array was designed and simulated for face recognition without the utilization of complex artificial neural network. Additionally, photon-modulated electrochemical doping is identified as the working principle for the photonic synaptic behaviors. Specifically, light stimulation manipulates ion insertion into the bulk of photoactive layer, leading to linear stepwise conductance modulation in a controlled manner. This light-regulated ionic flux behavior and resulting synaptic features make the device promising for interfacing living systems for adaptable prosthetics or bionic eyes. Specifically, the POECT device incorporates a photoactive layer composed of donor-acceptor bulk-heterojunction interfaces into a channel of an organic electrochemical transistors (OECTs). The resulting device presents significant photocurrent at low operating voltage (<1 V), enabling high-density nonvolatile conductance states for various applications, e.g., neuromorphic computing. The nonvolatile current is regulated by both light intensity and wavelength across the entire visible spectrum, demonstrating the capabilities of utilizing the POECT device for a wide range of biosensor applications, e.g., perceiving and memorizing various visual information applied to the device.

The POECT device of the present disclosure is a three-terminal device, including a gate adapted to receive a voltage for activating the device; a drain; and a source, wherein the source is typically coupled to ground and the drain is coupled to a voltage source via a load. When a voltage is applied to the gate, the device turns on allowing a drain to source current from the voltage source. The drain to source area is disposed over a channel that is made from a photoactive layer composed of donor-acceptor bulk-heterojunction interfaces. Thus, application of light i) enhances the drain to source current, and ii) provides a memory function. In other words, when the light is removed from the channel, the drain to source current retains some or all of its enhanced current, and when the light is re-established at the channel, the drain to source current enhances again from the previous enhanced position rather than from an initial position before light was applied. The POECT device of the present disclosure can also be reset, i.e., the memory erased by applying the proper voltage to the gate.

In contrast to electrical signal, light allows ultrafast signal transmission with limited crosstalk, enabling a computational domain that is inaccessible by pure electrical devices. Light has also been widely used as the stimulation method in bioelectronics to regulate cell activity due to its wireless communication with high spatial and temporal resolution. Thus, the POECT device of the present disclosure is adapted to provide a light-gated fast acting device usable in a variety of applications, including biosensors, e.g., a synaptic device (photonic synapses) for a variety of biological applications, e.g., neuromorphic computing and other biological applications. Furthermore, the addition of light signal acquiring capability to traditional electrical synaptic devices will offer the opportunity to emulate the function of biological elements, e.g., human retina for image preprocessing and recognition.

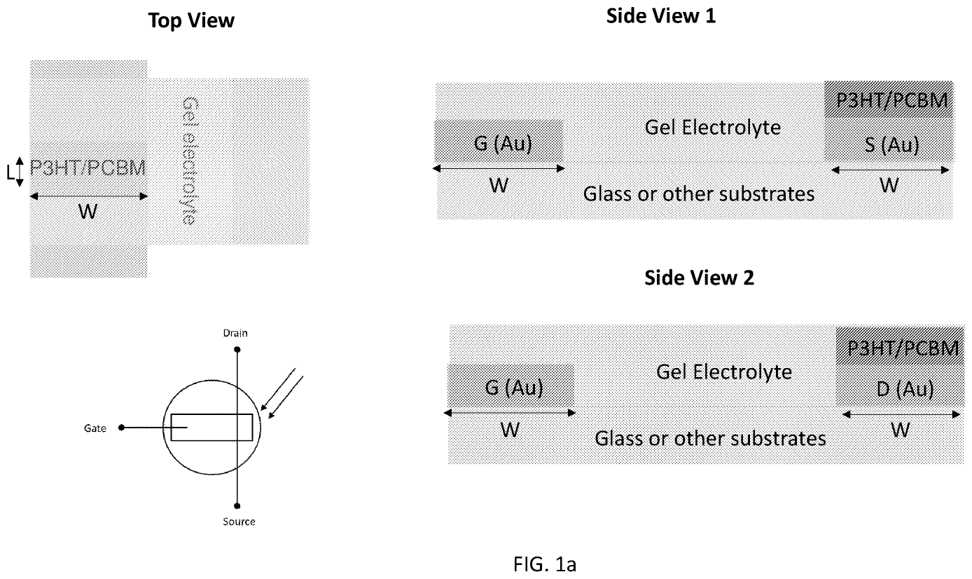

Referring to FIG. 1a, a sideview schematic of the POECT device according to the present disclosure is provided. The POECT device includes a substrate, three terminals (or electrodes) including gate, drain, and source, an electrolyte partially disposed between the terminals, and a channel disposed between or under the drain and source terminals. The electrolyte provides an ion transport mechanism between the gate terminal and the channel. An example electrolyte material is Poly(ethylene glycol) diacrylate (PEGDA)/lithium bis(trifluoromethane)sulfonimide (LiTFSI)/propylene carbonate (PC) utilized in a gel form. Other suitable electrolytes may be used, as is known to a person having ordinary skill in the art. The area between and under the drain and source terminals is occupied by a photovoltaic material. Once such material is a combination of poly(3-hexylthiophene) (P₃HT) and [6,6]-phenyl C61-butyric acid methylester (PCBM).

Referring to FIG. 1b, a schematic of the POECT device of the present disclosure is shown with various components called out. In the example shown in FIG. 1b, the substrate is made of glass, however, a number of other substrates are also possible, as known to a person having ordinary skill in the art. Furthermore, the three terminals (gate, drain, and source) are made of gold, while other conductive materials are also possible, as known to a person having ordinary skill in the art. The memory aspect of the POECT device of the present disclosure is demonstrated in FIG. 1b, wherein as optical pulses are introduced to the channel, the signal intensity of the POECT device increases in a non-volatile manner.

Additionally, FIG. 1b provides a series of voltage and current graphs that are used to depict the operation of the POECT device of the present disclosure. In particular, by applying a voltage to the gate, the device is turned on and is allowed to establish a channel to thereby allow conduction of a current between the drain and the source terminals governed by a load coupled to the drain or source terminals, as is known to a person having ordinary skill in the art. In this mode the device is deemed as being on. When the gate voltage is removed, the device turns off, as indicated by a decaying drain-to-source current. This behavior is shown as Cycle 1. However, if a light pulse is applied during cycle 2a when the device is turned on (i.e., with the gate voltage is on and stable), the device turns back on, in which case the drain-to-source current increases above the drain-to-source current in the on state of cycle 1. This increase in current is shown as ΔI_{DS_on}. After the light is turned off, the drain-to-source current decays but remains above the on state of cycle 1. This difference is referred to as ΔI_{DS_Mem} which can be used to establish the memory nature of the POETC device of the present disclosure. In cycle 2b, another light pulse is applied, which again causes the drain-to-source current to elevate above the drain-to-source current of cycle 2a by about the same ΔI_{DS_on} shown in cycle 2a. Again, once the light is turned off, the drain-to-source current decays, but this current remains above the on state of cycle 2a, again having a difference of about ΔI_{DS_Mem} which again can be used to establish the memory nature of the POETC device of the present disclosure. In cycle 3, shown in FIG. 1b, the gate voltage is reversed (as depicted by ΔVₑᵣₐₛₑ) which causes the memory aspect of the POETC device to be erased. Thus, in cycle 4, the device returns to its operation as shown in cycle 1.

In order to show the effectiveness of the POECT device of the present disclosure, (a P₃HT and PCBM mixture was used as the photoactive material and deposited in the channel, due to its well-stablished optoelectronic properties and electrochemical stability. Poly(ethylene glycol) diacrylate (PEGDA)/lithium bis(trifluoromethane) sulfonimide (LiTFSI)/propylene carbonate (PC) was utilized as the gel electrolyte since it offers good ion conductivity and processability.

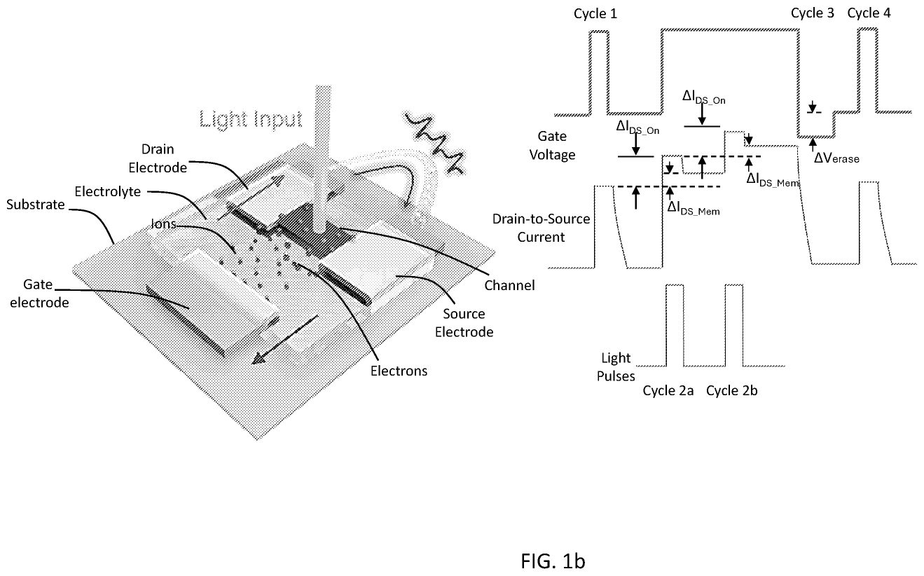

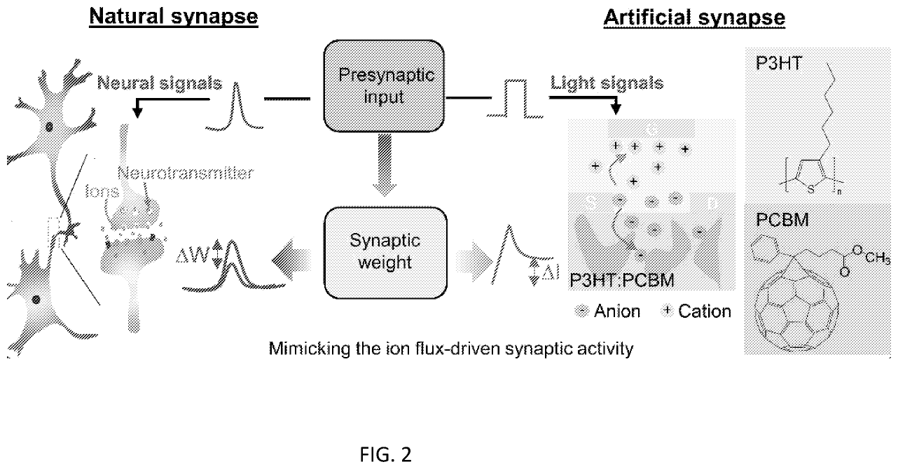

Referring to FIG. 2, a schematic illustration of a biological synapse and a schematic illustration of photonic synaptic device (i.e., the POECT device) are shown. In the biological system, the action potential (neural signal) causes presynaptic neurons to release transmitters, which binds to a receptor on the postsynaptic neuron. This process triggers the activation of ion channel and leads to ion flux. In the synaptic device, light induces charge carrier generation and ion transport, which results in a nonvolatile conductance change.

In the human visual system, optical information can be captured and transduced into neural signals by the retina and sent to the brain for vision memorization and recognition. For the emulation of the biological visual system, an intelligent vision system is disclosed herein including an image capture subsystem, an image memory subsystem, and an image recognition subsystem, each with the integrated function of light perception, light-to-electrical signal transduction and memorization, as shown in FIG. 1b. As such, the intelligent vision system is able to perceive and remember the image information without the assistance of software programming. Based on the past learning experience and the intrinsic photonic response of the synaptic devices, the image recognition can be realized with the intelligent vision system of the present disclosure.

Furthermore, the memory formation in human brain relies on ion flux-driven synaptic activity. As illustrated in FIG. 2, signals are communicated between neurons in the brain through a conjunction known as a synapse, where action potential from presynaptic neurons triggers the release of the chemical neurotransmitters to postsynaptic neurons and leads an ion flow. Repeated signal talks regulate synapse connection strengths (ΔW) for numerous neurons, which contributes to the human memory of perceived visual information. To emulate this ion flux-modulated synaptic activity and build the optically controlled photonic synapse in FIG. 1b, the POECT devices were utilized to construct the building block of the intelligent vision system. The POECT devices rely on bulk electrochemical doping, where ions are injected into thin film channel in response to a gate voltage input, resulting in a channel conductance change. Consequently, the donor-acceptor bulk heterojunction are utilized as the photoactive layer. As shown in FIG. 2, light absorption can perturb electrochemical doping and the light-induced charge carriers in the bulk heterojunction will lead to ion transport from the electrolyte to channel for charge compensation. As such, light can serve as a presynaptic input to give a postsynaptic electrical signal. The resulted photon-induced ion diffusion leads to synaptic behaviors and memory effects (i.e., enhancement of I_{DS} current). Such a light-tunable electrochemical doping mechanism is indeed novel.

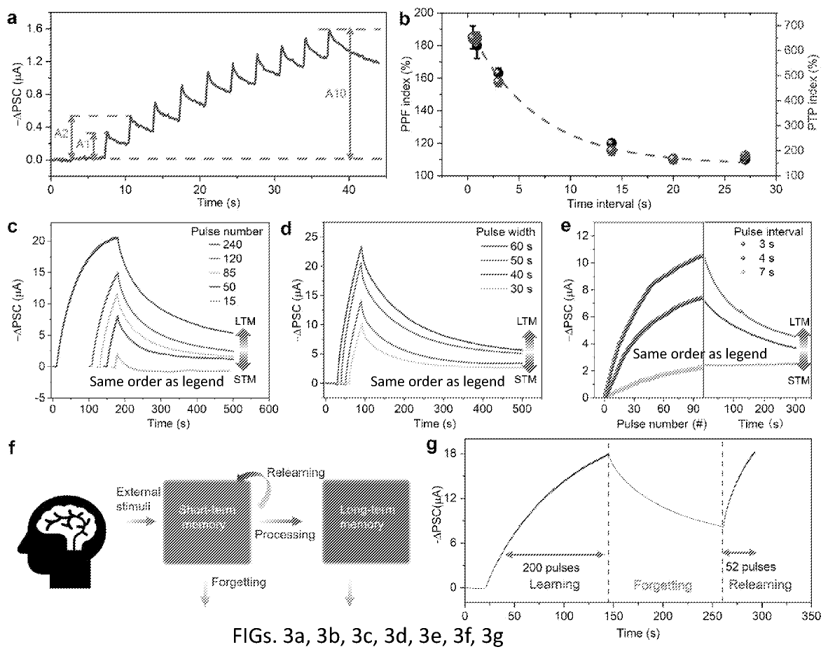

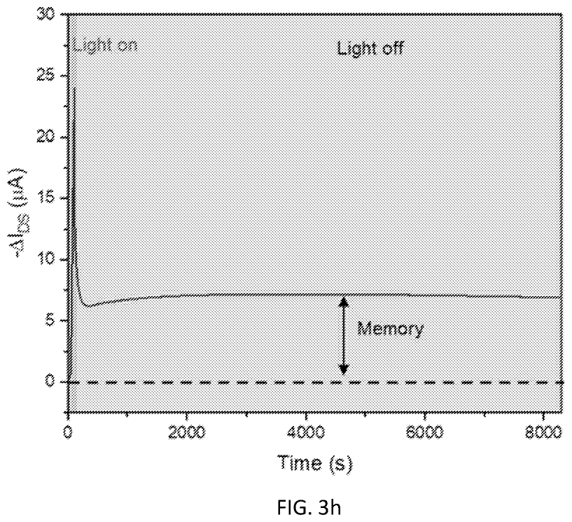

Taking advantage of the photonic nonvolatility of the devices, we used the devices to mimic the synaptic functions in the human brain. Short term plasticity (STP), which is crucial in processing and decoding temporal information in the human brain, was first emulated. Paired pulse facilitation (PPF) and post-tetanic potentiation (PTP) are two performance indicators in a biological synapse to evaluate STP. They present a synaptic process in which consecutive pulses can enhance the synapse response and are defined as:

$$PPF = ( \frac{{A}_{2}}{{A}_{1}} \times 100 ) \% \qquad ( 1 )$$

$$PTP = ( \frac{{A}_{10}}{{A}_{1}} \times 100 ) \% \qquad ( 2 )$$

Where, A₁, A₂ and A₁₀ represents the synapse weight change at the first, second, and tenth stimulation pulses, respectively. To emulate PPF and PTP, ten consecutive light pulses with duration and interval time of 0.4 s and 3 s were applied to the POECT device under a gate voltage of −0.6 V and a drain voltage of −0.8 V. As shown in FIG. 3a, which is a graph of postsynaptic current (PSC) in μA vs. time in seconds, the tenth pulse (A₁₀) is higher than the second (A₂) and the first light pulse (A₁). The current accumulation is due to memory feature of the POECT device such that when a previous light pulse is stopped, the photon induced charge carriers in the channel cannot decay to the starting level before the next pulse is applied. More charges will be accumulated with applying more light pulses. Thus, the interval time between the light pulses plays crucial role in determining the current enhancement. The PPF and PTP index as a function of light pulse intervals (from 0.5 s to 27.0 s) were evaluated in FIG. 3b which is a graph of PPF index vs. time interval in s. At interval time of 0.5 s, PPF and PTP index of 185 and 650 were obtained, respectively. Besides, both PPF and PTP show typical two-phase exponential behaviors as fitted by dashed line, which is also observed in biological synapses.

In contrast to STP, which represents the temporary synaptic weight change, LTP lays the foundation for memory formation. Generally, human memory can transform from short term to long term with the assistance of rehearsal events. Here, we emulated this transition by adjusting pulse number as shown in FIG. 3c which is a graph of PSC in μA vs. time in seconds with varying pulse numbers. With the increase of the pulse number from 15 to 240, the PSC increased dramatically, and it took longer to decay to original states, which indicates the transition from short-term memory (STM) to long-term memory (LTM). In addition, similar STM-LTM transitions were also observed when the light pulse width was increased or the light pulse intervals was shortened, as shown in FIGS. 3d-3e which are graphs of I_{DS} in μA and −ΔI_{DS} both vs. time in seconds, showing prolonging pulse width (7.0 mW/cm²) in FIG. 3d, and decreasing pulse intervals (7.0 mW/cm², tₚ=0.4 s) in FIG. 3e. Compared with STM, LTM indicates the PSC needs longer time to decay to the original level. The long-term retention of device memory over more than 2 hours was demonstrated as shown in FIG. 3h which is a graph of −ΔI_{DS} in μA vs. time in seconds, after responding to a 60-second light pulse. The memory improvement follows the human memory rules that greater memory can be formed by performing longer time of memorization or intermittent learning with high frequency. In addition, humans obtain new knowledge through three processes: learning, forgetting, and relearning, as shown in FIG. 3f which is an illustrative schematic of human learning processes. Usually the relearning process takes shorter amount of time compared with the first-time learning. This behavior was also achieved in the approach of the present disclosure, as shown in FIG. 3g which is a graph of −ΔPSC in μA vs. time in seconds. Referring to FIG. 3g, after 200 pulses of excitation, the device presented a PSC of 18 μA. This current decayed to 8 μA with time, which corresponded to the forgetting process, shown in FIG. 3f. Then the current can be restored to its previous state with only 52 pulses, again mimicking the learning process shown in FIG. 3f.

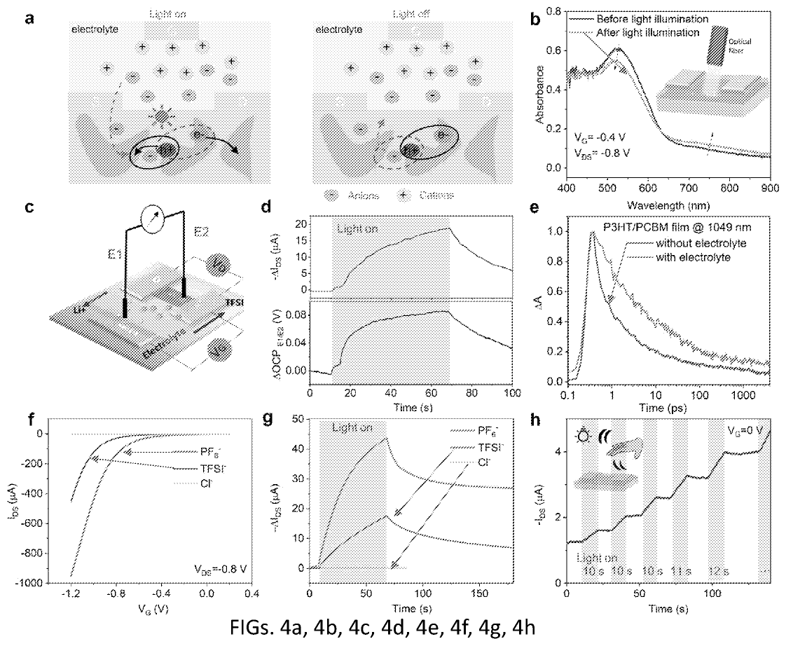

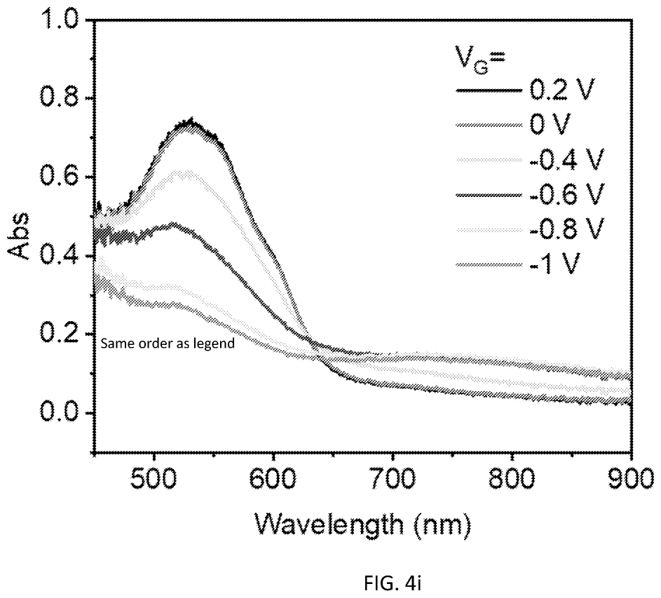

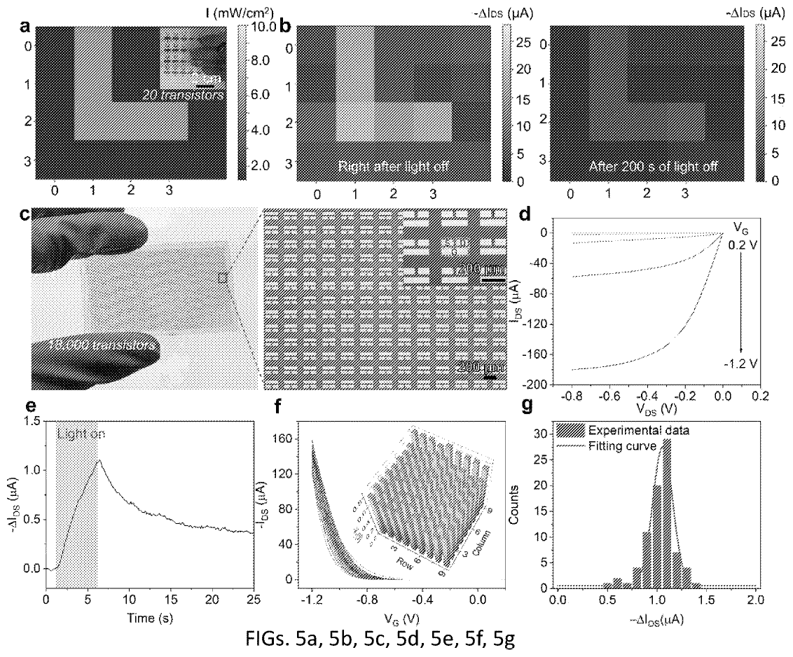

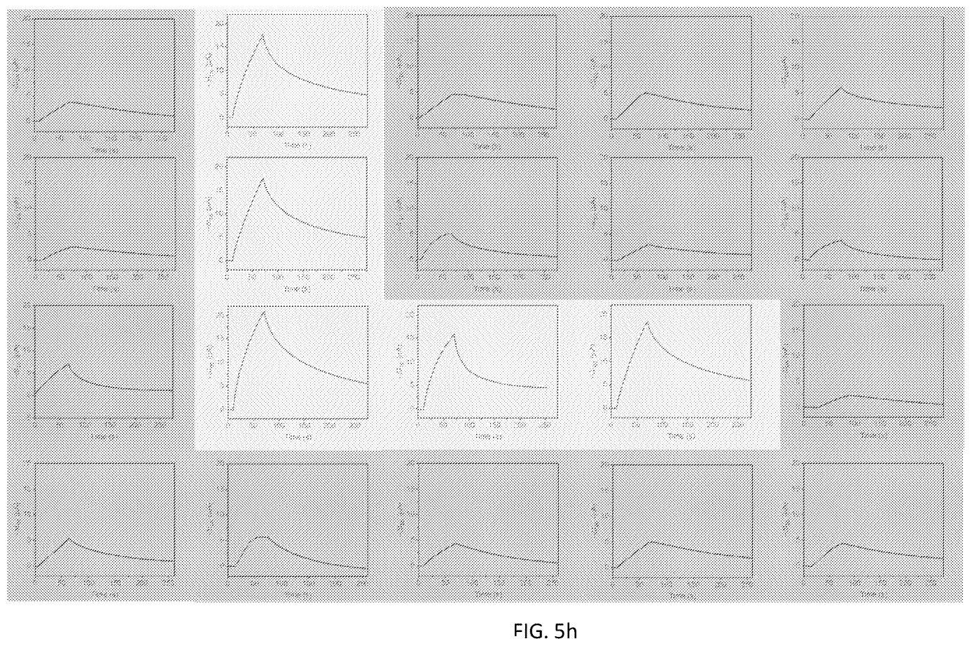

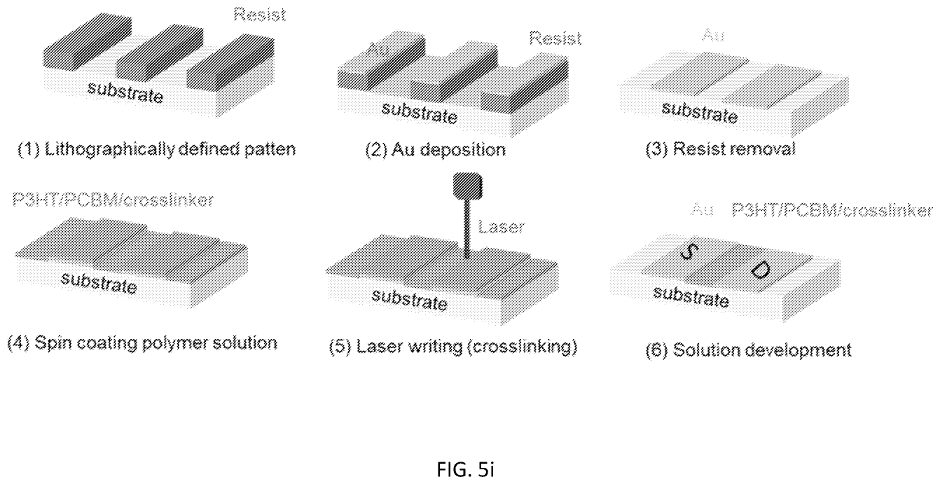

The present disclosure describes the desired non-volatile characteristics of the novel arrangement by photon-modulated electrochemical doping. Specifically, light absorption by donor-acceptor heterojunction of the POECT device produces charge carriers, which perturb electrochemical doping and is accompanied by the anion transport from electrolyte for charge compensation in the channel, as shown in FIG. 4a which is a schematic illustration showing photon-modulated electrochemical doping, in which light-induced charge carriers in the bulk heterojunctions leads to ion transport from the electrolyte for charge compensation are shown. After the light illumination, the presence of anions prohibits an immediate charge recombination. Thus, the higher carrier concentrations resulted from photon-modulated doping is detected as an increased drain current. When the light is switched off, the presence of anions around the doped P₃HT prohibits an immediate charge recombination, leading to a slow current decay and contributing to a nonvolatile memory current. To validate the photon-modulated electrochemical doping, first an in-situ spectroscopic experiment is performed before and after light exposure. The experimental setup is illustrated in FIG. 4b inset (FIG. 4b, otherwise provides a graph of absorbance vs. wavelength in nm), where an optical fiber was positioned above the channel to monitor its absorbance change, and the setup was evaluated using spectroelectrochemistry experiment shown in FIG. 4i. A 60-seconds light exposure at 7.0 mW/cm² was applied to the device under specific applied voltage. As described previously, a nonvolatile current could be detected in response to the light illumination. Here, corresponding to this nonvolatile current change, a spectrum shift of the photoactive layer was observed after the light illumination. As shown in FIG. 4b, a decrease in the visible region and an increase at NIR region was observed in the spectrum, which suggests the photon-modulated doping of the photoactive materials. After the light exposure, the device spectrum can be recovered to pristine states with the application of a reverse gate voltage, suggesting that there is no irreversible photooxidation.

FIG. 4c is a schematic illustration of a five-electrode electrochemical cell, where two extra electrodes (E1, E2, e.g., Pt electrodes) are added to the POECT device of the present disclosure to monitor the ion migration. FIG. 4d provides simultaneous channel current change (I_{DS}) in μA and open circuit potential (OCP_{E1/E2}) in V both vs. time in seconds showing change in response to light illumination. FIG. 4e is a graph showing PCBM anion radical/polaron transient absorption decay kinetic trace of pristine P₃HT/PCBM film (blue) and the film with electrolyte (red). The plots are normalized to facilitate comparison. FIG. 4f provides a graph of −I_{DS} in μA vs. V_{G} in Volts showing the transfer characteristics of the device. FIG. 4g is a graph of −ΔI_{DS} in μA vs. time in seconds providing an illustration of photonic response at V_{G}=−0.6 V and V_{DS}=−0.8 V of the device in different electrolytes. FIG. 4h is a graph of −I_{DS} in μA vs. time in seconds providing an illustration of photonic response of the device to hand waves in an ambient light environment with LiPF₆ based gel electrolyte. The purple areas indicate the periods when the device was repeatedly exposed to ambient light during the hand waves.

Similar to human visual system, the photonic synapse can simultaneously process and memorize optical information. This integrated function allows us to build artificial visual systems with reductions in hardware and power consumption compared with conventional von Neumann computing architecture, known to a person having ordinary skill in the art. Thus, to demonstrate the function of image perception and memorization, we fabricated a 4×5 synaptic array with each of the synaptic device functioning independently, as shown in FIG. 5a which is an illustration of the image perception and memorization of letter “L” on which L-shaped light was projected onto a 4×5 synaptic array composed of POECT devices, where the devices at letter position were stimulated with light intensity of 7.0 mW/cm², and the background devices were with light intensity of 2.0 mW/cm². The inset in FIG. 5a provides the image of the synaptic array. After 60 seconds of light exposure, the array revealed higher currents at letter “L” locations than the background, suggesting the pattern was successfully perceived, as shown in FIG. 5b, which provides resulting current mapping of the array right after the light is deactivated and 200 s thereafter. Specifically, after 200 seconds of the light off, this distribution of current difference can still be observed, demonstrating the device's pattern memory capabilities. The dynamic photonic response of each synaptic device in the array can be found in FIG. 5h which provides the photonic response of synaptic devices in a 4×5 synaptic array. As discussed above, the synapses at yellow regions are illuminated with light at intensity of 7.0 mW/cm², while the light illuminations at blue regions are at 2.0 mW/cm².

The footprint of the POECT device was further reduced with optical lithography technique since a high-density array is required for future higher resolution image perception and memorization. As shown in FIG. 5c, we fabricated a device array with 18,000 transistors on a 2.5×5 cm² glass substrate. The channel length and width of each device in the array are 10 μm and 50 μm, respectively. The device fabrication process is illustrated in FIG. 5i. To reduce the device footprint, we first used a typical photolithography for microelectrode patterning, as shown in FIG. 5i processes (1)-(3). Then a crosslinker molecule, bis(fluorophenyl azide) (bisFA), was blended with P₃HT/PCBM (25 mg/mL in chloroform) at a weight ratio of 5% for channel materials printing, as shown in FIG. 5i processes (4) to (6).

The downscaled organic electrochemical transistor retains the typical electrochemical performance and photonic response. As shown in FIG. 5d (which is a graph of I_{DS} in μA vs V_{DS} in volts) and FIG. 5e (which is a graph of −ΔI_{DS} in μA vs. time in seconds, the device shows a standard output curve with clear linear and saturation regions, as well as exhibits typical photocurrent and memory behavior. To evaluate the uniformity of the array. We randomly selected 81 devices and examined their transfer characteristics and photonic responses. As shown in FIG. 5f which is a graph of −I_{DS} in μA vs. V_{G} in volts, the transfer curves distribution of the devices is relatively concentrated. The inset displays the threshold voltage distribution of the devices extracted from the transfer curves, which shows a uniform value of around 0.75 V with a relatively small standard deviation. In FIG. 5g which is a histogram of −ΔI_{DS} in μA, the distribution of photonic response of these 81 devices is narrow, with 94% of devices exhibiting current change of more than 0.8 μA. The fitting results indicate that the distribution of photocurrent is a normal distribution.

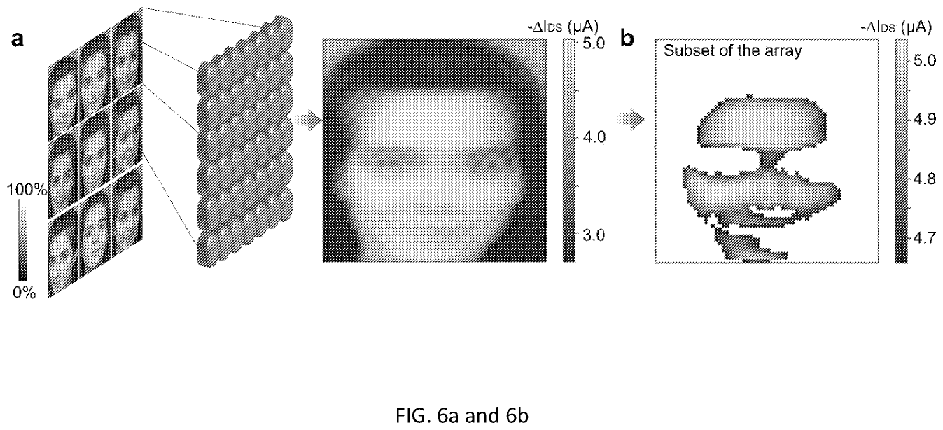

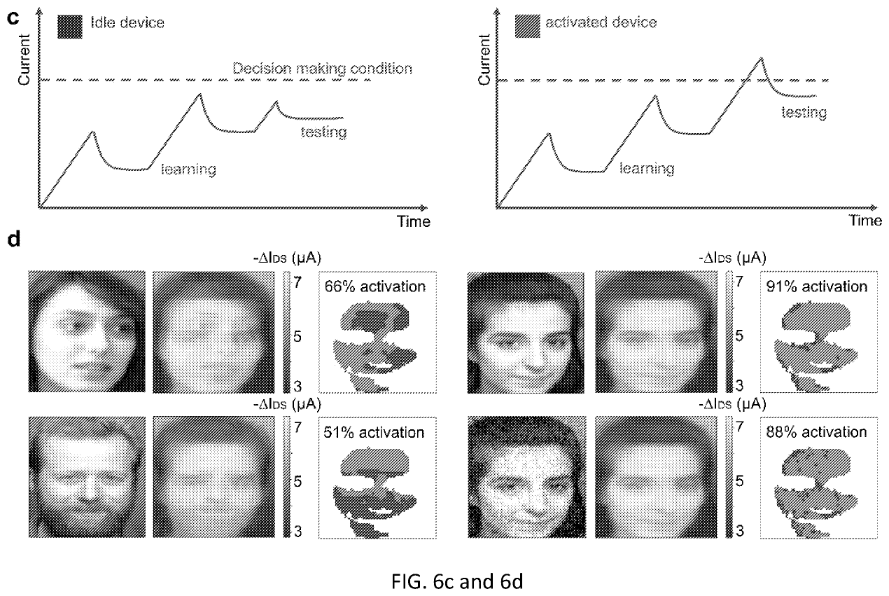

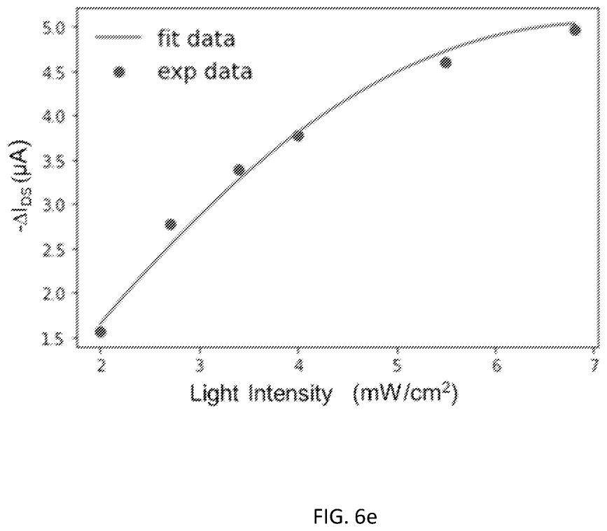

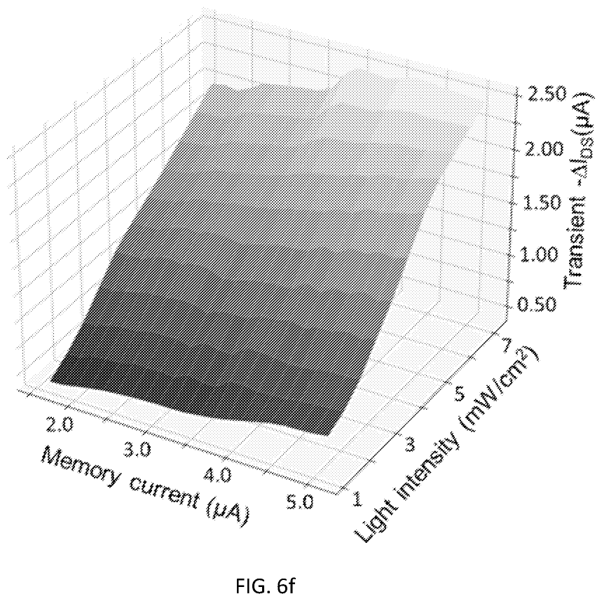

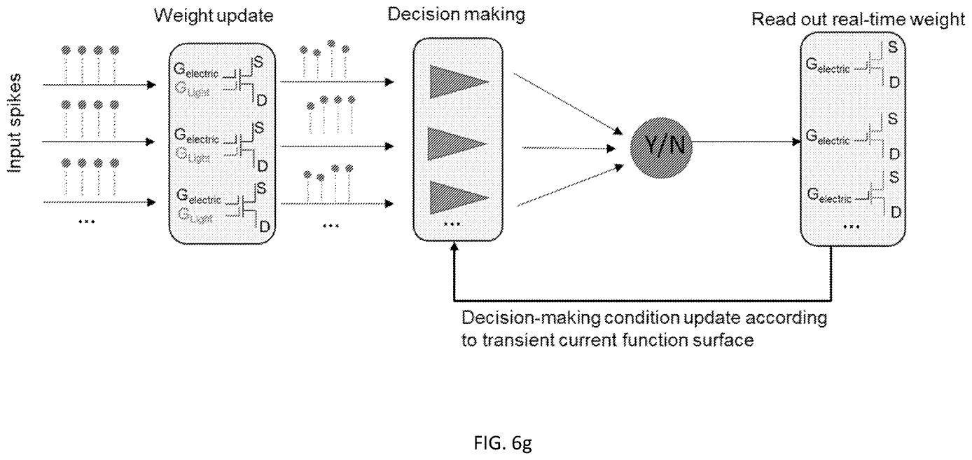

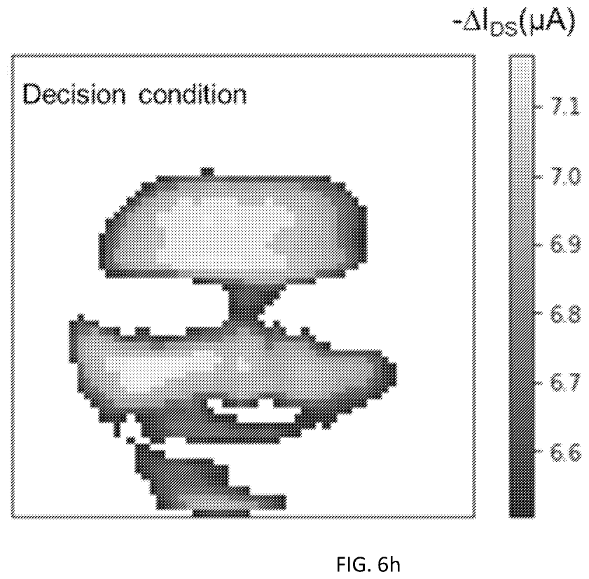

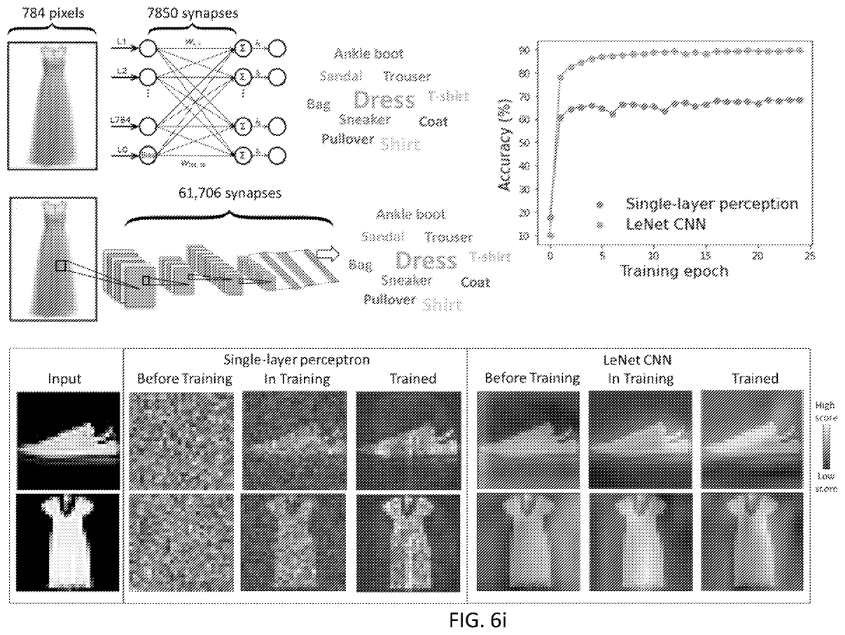

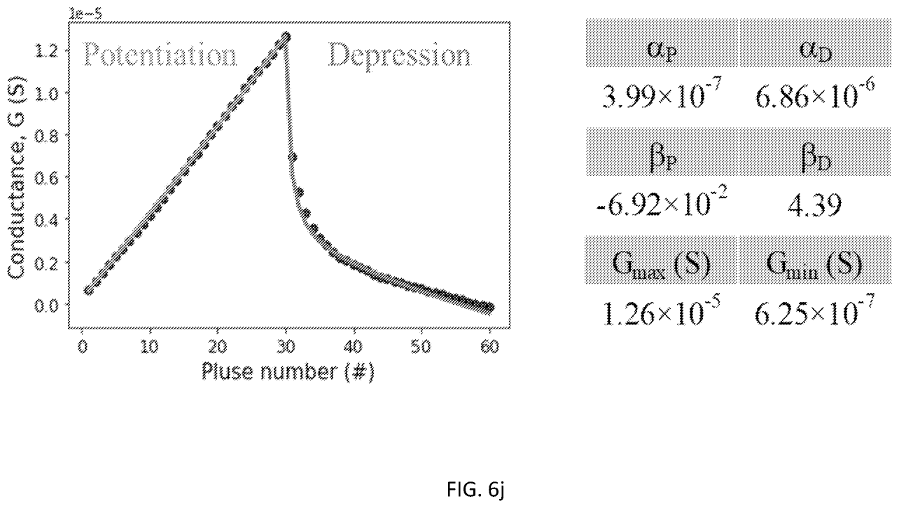

Based on the experimental results of image recognition, we further simulated a 64×64 array of optical synapses as the intelligent vision system according to the present disclosure for face recognition. This face recognition simulation includes model training and testing. First, the synaptic array was trained with nine grayscale face images of a woman with distinct facial expression and orientations as shown in FIG. 6a, which is an illustration of the model training of intelligent vision system, where the optical signals from nine face images of a woman was input to a simulated 64×64 synaptic array, generating a memory current mapping. To input the information to the synaptic array, the optical signals of the images were normalized to the light intensities in the device detection dynamic range and sampled to 64×64 pixels. With the light intensity-to-electrical memory transformations on each synaptic device, shown in FIG. 6e which is a graph of −ΔI_{DS} in μA vs. light intensity in mW/cm² indicating a light induced nonvolatile current change as a function of light intensity; a memory current mapping learned from the nine pictures was output and shown in FIG. 6a. The locations with higher memory current correspond to face regions with higher light reflection. Secondly, we selected a subset of the array as shown in FIG. 6b for building the face recognition model, which has high memory current and thus can represent the face characteristic outline. In this subregion, the face recognition model is constructed based on the predictive capability of devices' transient currents under a specific illumination condition, as shown in FIG. 6f which depicts a function surface showing the memory current-dependent and light intensity-dependent transient current change. The detailed workflow of the model construction can be found in FIG. 6g presenting a protocol for dynamically updating decision-making condition using real-time weight reading. Based on the fitted function in FIG. 6f, a controller (not shown) running software on a non-transient memory can automatically predict the photonic transient currents from intelligent vision system when it is exposed to test faces. This capability allows an efficient face recognition model. In this model, we firstly determined the feature space of the learned memories in the synaptic arrays. We selected devices with relatively high memory currents (75% percentile as a threshold) as the feature devices, which automatically locates the characteristic outline of the target face (FIG. 6b). We adaptively set the recognition decision-making criteria for feature devices based on the predictive capability for transient currents of synaptic devices under varying illumination and memory conditions (shown in FIG. 6f). If we implement the trained intelligent vision system with face images from the same woman (positive cases), all feature devices will provide similar current weight updates as the training process. In contrast, if the intelligent vision system is exposed to other face images (negative cases) which have low reflection visual features in the feature space, the photocurrents at corresponding locations will be lower than expected values in the positive recognition. To utilize the discriminative response of transient photocurrent for face recognition, we predicted the photocurrents for all feature devices in the positive case using the training face images, trained memories and the function surface, as shown in the FIG. 6h. In addition, we multiplied a tolerance ratio (0.9) with predicted photocurrents and set these values as decision-making conditions.

Referring to FIG. 6g, real-time wights can be read out through drain current without influencing the device conductance in our three-terminal device structure. Then, they can be used for updating the decision-making conditions via transient current function surface.

With this model, we can adaptively set a decision-making condition for each synaptic device, as illustrated in FIG. 6c, which provide graphs of current vs. time for idle and activated devices. As a result, if a synapse receives visual signal from the identical woman's face, a transient photonic current goes beyond its decision-condition line and the device is recorded as an activation status. Otherwise, an idle status is recorded. Lastly, we performed the face recognition tests with our model using four example faces. In FIG. 6d where an array shows low activation rate to true negative images, while it shows high activation rate to true positive images, even when these images are from different orientation or added with signal noise compared to the training face images. When face images of other woman and man were tested, the activation rates of the face recognition system were smaller than 70%, indicating they were correctly rejected from our model as true negative cases. In contrast, the intelligent vision system showed more than 85% of activation rates when testing with the target woman's faces (representing true positive cases), even though they have different orientation or noise level compared to the training face images. This means the face recognition system can effectively learn critical visual features deviated from the training images for recognizing target images. In addition, we also developed and evaluated a single-layer perception model and a deep LeNet CNN model using our synapse as the building block for fashion product classification. The synapse-based LeNet model is capable of recognizing fashion products with 90% accuracy after 25 epochs of training, providing a proof-of-concept for implementing our device in hardware-based artificial intelligence (AI) training acceleration. The details of the modeling can be found in FIGS. 6i and 6j.

Specifically, FIG. 6i provides simulation results of hardware neural networks using optical synapses including configuration of a single-layer perceptron, configuration of a LeNet CNN model, recognition rates of two models with respect to training epochs, and evaluation of model training progression using synaptic weights visualization and Grad-CAM heatmap.

A variety of hardware frameworks are available to implement the matrix multiplication and convolution computing using the artificial synapses, which enables the construction of hardware neural networks for artificial intelligence applications. A single-layer perceptron and a deep LeNet convolutional neural network (CNN) were simulated using our optical synapses as shown in FIG. 6i. They were both trained and tested using a Fashion-MINIST dataset, which is a recently developed image dataset for benchmarking machine learning algorithms. Fashion-MINIST comprises of 28×28 pixel grayscale images of 70000 fashion products from 10 categories.

Based on this object recognition task, the perceptron is constructed with 785 input neurons, corresponding to the number of image pixels (28×28+1), and 10 output neurons with a softmax layer, corresponding to 10 fashion product categories. Input and output neurons are fully connected by 7850 (785×10) synapses. LeNet is a deep CNN model, including 3 convolution layers, 2 pooling layers, 3 fully connected layers and a softmax layer. Two convolution layers have 6 kernels with size of 5×5 and 26 kernels with size of 5×5, respectively. Three fully connected layers contain 16×5×5×120, 120×84 and 84×10 weights, respectively. For each layer in the hardware neural network models, the input voltage signals (V) are multiplied (fully connected layer) or convolved (convolution layer) with synaptic weights (W), resulting in learned features comprising current signals (I=W·V or I=W*V). These current signals are then passed through activation function and convert into voltage signals for the computation in the next layer (V=f_{ReLu}I or V=f_{softmax}I). In the training phase of the hardware neural network, we update the weights of optical synapses by comparing the softmax result vectors with fashion product ground-truth categories using a cross entropy criterion and Adam optimization algorithm.

FIG. 6j provide parameter fitting of the device potentiation and depression pulse trains with 60 representative weight states, including superimposition of experimental data points and fitted curve, and fitted equation parameters.

To optimize synaptic weights in the training phase, a widely used hardware-based backpropagation (HDBP) algorithm has been adopted. More specifically, a differential pair of optical synapses are used to represent one synaptic weight (W=G⁺−G⁻). To update G⁺ and G⁻, each synapse is firstly determined whether in a potentiation or depression status based on the ΔW, which is calculated via cross entropy loss and Adam optimizer, as shown in equation (3).

$$state = \{ \begin{matrix}potentiation ( {G}^{+} ↑ and {G}^{-} ↓ ) , if Δ W > 0 \\ depression ( {G}^{+} ↓ and {G}^{-} ↑ ) , if Δ W < 0\end{matrix} \qquad ( 3 )$$

For the weight updating in the potentiation state, the G⁺ is designed to increase and G⁻ to be simultaneously decreased. On the opposite depression state, the G⁺ is designed to decreased and G⁻ to be increased as shown in equation (4).

$$Δ G = {G}_{n + 1} - {G}_{n} = \{ \begin{matrix}α {e}^{- β \frac{{G}_{n} - {G}_{min}}{{G}_{max} - {G}_{min}}} , if state = potentiation \\ - α {e}^{- β \frac{{G}_{max} - {G}_{n}}{{G}_{max} - {G}_{min}}} , if state = depression\end{matrix} \qquad ( 4 )$$

where Gₙ denotes the present conductance state of the optical synapses and Gₙ₊₁ denote the updated conductance state in the next training iteration, respectively. α denotes the step size of the conductance updating and β denotes the nonlinearity. Conductance updating functions (equation 2) are fitted using the characteristic behaviors of synapse operation and fitted parameters are shown in FIG. 6j. To avoid the scale issue, both G⁺ and G⁻ are initialized to Gₘᵢₙ when the synaptic conductance attains the maximum (Gₘₐₓ) or minimum (Gₘᵢₙ) values.

As shown in FIG. 6i, we demonstrated the object recognition performance of hardware neural networks built with optical synapses on the Fashion-MINIST dataset. In each epoch of simulation, the synaptic conductance weights were updated by the training of 60000 images of fashion products. Then we tested the network using 10000 testing images and recorded the recognition rates. Both single-layer perception and LeNet models converged within 25 epochs, demonstrating the excellent learning efficiency of the HDBP algorithm. As a result, recognition rates of 69.0% and 89.5% were achieved by single-layer perception and LeNet, respectively. To visualize the synaptic weight update and the model evolution, the synaptic weights connected to output neurons were visualized for the single-layer perceptron model. In addition, the gradient-weighted class activation mapping (Grad-CAM)¹⁰ technique was adopted to visualize the progress of the LeNet CNN model. Grad-CAM exploits the gradients of image classification in the backpropagation to locate the important regions in the image for the predicting, which is plotted using a heatmap. Herein, images of a sneaker and a dress are used for model evolution evaluation using both techniques in two models, respectively. The panel in FIG. 6i displays the synaptic weights corresponding to input images in different periods of modeling training. With the progress of the training, more clear fashion product images are mapped by the model, indicating the improved recognition performance. In the LeNet CNN model, the Grad-CAM heatmap is gradually moved to the edges of the object as shown in the superimposed images in the panel of FIG. 6i which are key features for differentiating fashion products. The change of the heatmap indicates the CNN model has become more intelligent for locating the key visual features in the image after the model training. This test performance and model evaluation demonstrate that our optical synapse can be effectively used as the basic computing unit to be implemented in deep neural network with a large number of parameters.

In summary, we have presented an intelligent vision system in three models for visual recognition tasks: (1) a single-layer intelligent vision system for binary face recognition. (2) a single-layer perceptron and (3) a LeNet CNN model for fashion product recognition. We have demonstrated the increase of model complexity can result in more powerful visual recognition performance. The CNN model (61,706 synapses) provides the most robust object recognition performance, while the intelligent vision system (64×64 synapses) can provide highly efficient binary face recognition by fully utilizing the optical synapse integrated functions of ambient light perception, light-to-electrical signal transduction and memorization. These simulations demonstrate that our optical synapse has the promise of building a wide range of hardware sensing and computing applications.

To test the intelligent vision system for image recognition a discriminator is needed to compare the trained array of POECT devices (i.e., the array with an image imprinted thereon) to a test image. Different types of discriminators can be designed and implemented for this task. For example, the trained array can be tested based on its memory attributes to arrive at a mathematical model representing I_{DS} currents of each transistor. This mathematical model can then be compared to a mathematical model associated with a test image. If the comparison is within a predetermined threshold, a match can be declared, or else, a mismatch can be declared. Alternatively, a discriminator can be based on a statistical view of the training array based on I_{DS} currents of each transistor which can be compared to a test array which has had an image to be compared imprinted thereon. If the comparison is within a predetermined threshold, a match can be declared, or else, a mismatch can be declared. Other discriminators are possible based on deep learning whereby the discriminator can learn from past comparisons to improve its performance.

Those having ordinary skill in the art will recognize that numerous modifications can be made to the specific implementations described above. The implementations should not be limited to the particular limitations described. Other implementations may be possible.

1. An intelligent vision system, comprising:
a training array of photonic-organic electrochemical transistor (POECT) devices, each device comprising:
a substrate;
three terminals including a gate, a drain, and a source disposed over the substrate, wherein space between the drain and the source forms a channel;
an electrolyte in fluid and electrical communication with the gate and the channel;
wherein the channel is formed of a photoactive layer composed of donor-acceptor bulk-heterojunction interfaces, each POECT device of the training array provides a memory feature when exposed to light;
wherein an image to be recognized is imprinted on the training array by exposing the training array with light corresponding with the image to be recognized, and
a discriminator configured to compare the training array with a test model associated with an image to be tested against the image to be recognized, wherein if the comparison between the test array and the test model provides a match greater than a predetermined threshold, the discriminator signals a match, else the discriminator signals a mismatch.

2. The intelligent vision system of claim 1, wherein the substrate is selected from the group consisting of glass, silicon, parylene, polyethylene, and a combination thereof.

3. The intelligent vision system of claim 1, wherein each of the three terminals are formed of a metal.

4. The intelligent vision system of claim 3, wherein the metal is selected from the group consisting of platinum, Au, ITO, Ag, Cu, and combination thereof.

5. The intelligent vision system of claim 1, wherein the electrolyte is selected from the group consisting of Lithium hexafluorophosphate (LiPF₆), Lithium bis(trifluoromethanesulfonyl)imide (LiTFSI), and Tetrabutylammonium chloride (TBACl: (C₄H₉)₄NCl)), and a combination thereof.

6. The intelligent vision system of claim 1, wherein the photoactive layer composed of donor-acceptor bulk-heterojunction interfaces includes poly(3-hexylthiophene) (P₃HT) and [6,6]-phenyl C61-butyric acid methylester (PCBM).

7. The intelligent vision system of claim 1, wherein application of voltage to the gate terminal, turns on the device thereby allowing a drain to source current when the drain terminal is coupled to a voltage source having a magnitude and the source terminal is coupled to ground.

8. The intelligent vision system of claim 7, wherein application of light to the channel, results in an enhancement of the drain to source current.

9. The intelligent vision system of claim 8, wherein removal of the light applied to the channel, results in a device memory to the enhanced drain to source current.

10. The intelligent vision system of claim 9, wherein the device memory is erased by applying a voltage to the gate terminal.

11. The intelligent vision system of claim 8, wherein the drain to source current is selectively influenced based on the voltage placed on the gate voltage.

12. The intelligent vision system of claim 8, wherein the drain to source current is selectively influenced based on the magnitude of the source voltage coupled to the drain.

13. The intelligent vision system of claim 8, wherein the drain to source current is selectively influenced based on intensity of light applied to the channel.

14. The intelligent vision system of claim 8, wherein the drain to source current is selectively influenced based on wavelength of light applied to the channel.

15. The intelligent vision system of claim 8, wherein the drain to source current is selectively influenced based on selection of material of the electrolyte.

16. The intelligent vision system of claim 1, wherein the test model is based on a mathematical model associated with the test image.

17. The intelligent vision system of claim 1, wherein the test model is based on a test array on which the test image has been imprinted.

18. A training array of photonic-organic electrochemical transistor (POECT) devices, each device comprising:
a substrate;
three terminals including a gate, a drain, and a source disposed over the substrate, wherein space between the drain and the source forms a channel;
an electrolyte in fluid and electrical communication with the gate and the channel;
wherein the channel is formed of a photoactive layer composed of donor-acceptor bulk-heterojunction interfaces, each POECT device of the training array provides a memory feature when exposed to light;
wherein the training array is configured to have an image to be recognized imprinted on the training array by exposing the training array to light corresponding with the image to be recognized.

19. The training array of claim 18, wherein the substrate is selected from the group consisting of glass, silicon, parylene, polyethylene, and a combination thereof, and each of the three terminals are formed of a metal and wherein the metal is selected from the group consisting of platinum, Au, ITO, Ag, Cu, and combination thereof.

20. The training array of claim 18, wherein the electrolyte is selected from the group consisting of Lithium hexafluorophosphate (LiPF₆), Lithium bis(trifluoromethanesulfonyl)imide (LiTFSI), and Tetrabutylammonium chloride (TBACl: (C₄H₉)₄NCl)), and a combination thereof, and wherein the photoactive layer composed of donor-acceptor bulk-heterojunction interfaces includes poly(3-hexylthiophene) (P₃HT) and [6,6]-phenyl C61-butyric acid methylester (PCBM).
